(19) United States
(12) Patent Application Publication
(10) Pub. No.: US 2004/0152294 A1
(43) Pub. Date: Aug. 5, 2004

(54) Method for forming metal line of semiconductor device

(76) Inventor: Kyeong Keun Choi, Suwon-Shi (KR)

Correspondence Address: MARSHALL, GERSTEIN & BORUN LLP, 6300 SEARS TOWER, 233 S. WACKER DRIVE, CHICAGO, IL, 60606, US

(21) Appl. No.: 10/720,976

(22) Filed: Nov. 24, 2003

(30) Foreign Application Priority Data
Feb. 5, 2003 (KR) 2003-7099

(51) Int. Cl. H01L 21/4763; H01L 21/44

(52) U.S. Cl. 438/622; 438/639; 438/687

(57) ABSTRACT

The present invention provides a method for forming a metal line of a semiconductor device comprising the steps of: forming a via plug on a semiconductor substrate; forming an interlayer insulating film on the semiconductor substrate, on which the via plug is formed; forming a trench by patterning the interlayer insulating film in order to form an upper line to be connected to the via plug; depositing a spacer insulating film, which is more invulnerable to a mechanical stress than the interlayer insulating film, on the semiconductor substrate on which the trench is formed; forming a spacer on a side wall of the trench by performing an anisotropic-dry-etching of the spacer insulating film; and forming a metal line by burying the trench with a conductive material.

### BACKGROUND

1. Field of the Invention

The present invention relates to a method for manufacturing a semiconductor device and, more specifically, to a method for forming a metal line of a semiconductor device, wherein a spacer is formed at a side wall of a trench which is formed in an interlayer insulating film, thereby compensating for vulnerability of mechanical properties of the interlayer insulating film and suppressing such a phenomenon that the interlayer film is eroded or the metal line is dished.

2. Discussion of Related Art

In an inductor of a semiconductor device, a metal line is thick and an interval between the metal lines is narrow, so that there is a problem that an interlayer insulating film is broken during a chemical mechanical polishing (CMP) process of the metal line formation. The problem is more critical in case of using an oxide film having a low dielectric constant as an interlayer insulating film. In general, since the low dielectric oxide film used as the interlayer insulating film is porous and contains a large quantity of carbon, it is vulnerable to a mechanical stress. In particular, as the line is still thicker, the vulnerability of the mechanical properties is further worsened. Unfortunately, the low dielectric oxide film must be inevitably used in order to obtain a high Quality factor (Q factor). Moreover, there are problems that the interlayer is eroded and the metal line is dished.

Accordingly, there has been a necessity for solving the aforementioned problems, such as the vulnerability of the mechanical properties, the erosion of the oxide film, the dishing in the metal line, and so on, which occur in case of using the low dielectric film as an interlayer insulating film.

### SUMMARY OF THE INVENTION

The present invention is directed to provide a method for manufacturing a semiconductor device and, more specifically, to a method for forming a metal line of a semiconductor device, wherein a spacer is formed at a side wall of a trench which is formed in an interlayer insulating film, thereby compensating for vulnerability of mechanical properties of the interlayer insulating film and suppressing such a phenomenon that the interlayer film is eroded and the metal line is dished.

One aspect of the present invention is to provide a method for forming a metal line of a semiconductor device comprising the steps of: forming a via plug on a semiconductor substrate; forming an interlayer insulating film on the semiconductor substrate, on which the via plug is formed; forming a trench by patterning the interlayer insulating film in order to form an upper line to be connected to the via plug; depositing a spacer insulating film, which is more invulnerable to a mechanical stress than the interlayer insulating film, on the semiconductor substrate on which the trench is formed; forming a spacer on a side wall of the trench by performing an anisotropic-dry-etching of the spacer insulating film; and forming a metal line by burying the trench with a conductive material.

In the aforementioned of a method for forming a metal line of a semiconductor device according to another embodiment of the present invention, the spacer insulating film is formed by using an Si₃N₄ film or an SiC film which has a mechanical strength stronger than that of the interlayer insulation film and can be used as a metal diffusion barrier film. Further, the spacer insulating film is preferably deposited by using a plasma-enhanced chemical vapor deposition (PE-CVD) method at a temperature in the range of 200° C. to 450° C. under a pressure in the range of 0.01 torr to 500 torr.

In the aforementioned of a method for forming a metal line of a semiconductor device according to another embodiment of the present invention, the spacer insulating film is deposited to have a thickness in the range of 50 Å to 1500 Å.

In the aforementioned of a method for forming a metal line of a semiconductor device according to another embodiment of the present invention, the anisotropic-drying-etching may be a reactive ion etching.

In the aforementioned of a method for forming a metal line of a semiconductor device according to another embodiment of the present invention, the interlayer insulating film is an oxide film having a lower dielectric constant and formed by using an spin on glass (SOG) film, an fluorine doped tetra ethyl ortho silicate (F-TEOS) film, a carbon doped dielectric (COD) film or a porous low dielectric oxide film.

In the aforementioned of a method for forming a metal line of a semiconductor device according to another embodiment of the present invention, the step of forming the via plug comprises the steps of: forming a lower line on the semiconductor substrate; forming a second interlayer insulating film on the semiconductor substrate, on which the lower line is formed; forming a via hole by patterning the second interlayer insulating film in order to connect the lower line with the upper line; and forming a via plug by burying the via hole with a conductive metal.

In the aforementioned of a method for forming a metal line of a semiconductor device according to another embodiment of the present invention, the step of forming the metal line comprises the steps of: depositing a diffusion barrier film along a step difference of the semiconductor substrate on which the spacer is formed; depositing a copper seed layer on the diffusion barrier film; forming a copper film on the copper seed layer by using an electroplating method, thereby burying an opening portion; and forming the metal line by planarizing the copper film.

### BRIEF DESCRIPTION OF THE DRAWINGS

FIGS. 1 to 6 are cross-sectional views for explaining a method for forming a metal line of a semiconductor in accordance with a preferred embodiment of the present invention.

### DETAILED DESCRIPTION OF PREFERRED EMBODIMENTS

Now the preferred embodiments according to the present invention will be described with reference to the accompanying drawings. Since the preferred embodiments are provided for the purpose that the ordinary skilled in the art are able to understand the present invention, they may be modified in various manners and the scope of the present invention is not limited by the preferred embodiment described later. The later referred phrase, “a layer is formed on the other layer” means that the former layer is formed just on the latter layer, otherwise that some layers may be disposed between the former and latter layers. In addition, in the scale of the drawings, the thickness or size of the layers may be exaggeratedly illustrated for convenience and clearness of explanation of the present invention. The same reference numerals on the drawings indicate the same components.

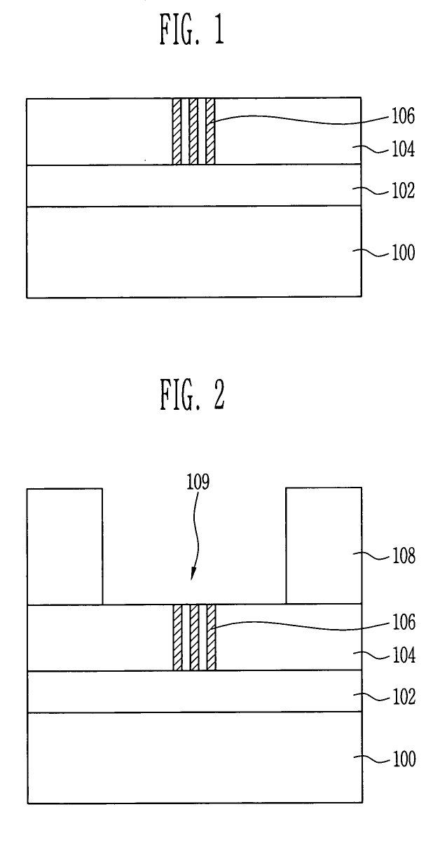

FIGS. 1 to 6 are cross-sectional views for explaining a method for forming a metal line of a semiconductor in accordance with a preferred embodiment of the present invention.

Referring to FIG. 1, a semiconductor substrate 100 where a semiconductor device (not shown) such as a transistor is formed is prepared. A lower line 102 is formed on the semiconductor substrate 100. The lower line 102 is formed with a conductive film such as a Cu film, an Al film, a W film, and so on. Subsequently, a first interlayer insulating film 104 is formed on the lower line 102. The first interlayer insulating film 104 is formed with such as an spin on glass (SOG) film, a tetra ethyl ortho silicate (TEOS) film, an fluorine doped tetra ethyl ortho silicate (F-TEOS) film, a phosphorus silicate glass (PSG) film, a boro phosphorus silicate glass (BPSG) film, and so on. The first interlayer insulating film 104 is formed to have a thickness of 3,000 Å to 10,000 Å by a deposition process in accordance with a design rule.

A first photosensitive film pattern (not shown) for defining a via hole which opens the lower line 102 is formed on the first interlayer insulating film 104. The first interlayer insulating film 104 is subjected to an etching process by using the first photosensitive film pattern as a mask to form the via hole. The etching process for forming the via hole utilizes a mixed gas of C₄F₈ gas or C₅F₈ gas, with O₂ gas, N₂ gas, and Ar gas. More specifically, the etching process is carried out by injecting a mixed gas of C₄F₈ gas or C₅F₈ gas in the range of 3 sccm to 200 sccm, O₂ gas in the range of 5 sccm to 500 sccm, N₂ gas in the range of 10 sccm to 2000 sccm, and Ar gas in the range of 100 sccm to 3000 sccm under conditions of a pressure in the range of 10 mT to 400 mT, a source power in the range of 100 W to 3000 W, and a bias power in the range of 500 W to 1800 W.

The via hole is buried with a conductive material to form a via plug 106. The via plug 106 is formed with a Cu film, a Pt film, an Ag film, an Al film, or a W film.

Referring to FIG. 2, a second interlayer insulating film 108 is formed on the via plug 106 and the first interlayer insulating film 104. The second interlayer insulating film 108 is formed by using a low dielectric oxide film. For example, the interlayer second insulating film 108 is formed by using an spin on glass (SOG) film, an fluorine doped tetra ethyl ortho silicate (F-TEOS) film, a carbon doped dielectric (COD) film or a porous low dielectric oxide film. The second interlayer insulating film 108 is deposited to have a thickness in the range of 0.5 μm to an order of 10 μm in order to satisfy a desired quality factor (Q).

Subsequently, a second photosensitive film pattern (not shown) for defining a trench 109 is formed on the semiconductor substrate 100. The second interlayer insulating film 108 is subjected to an etching process by using the second photosensitive film pattern as a mask to form the trench 109 for exposing the via plug 106. More specifically, plasma that is made by activating C₄F₈ gas, O₂ gas, N₂ gas, or Ar gas, for example, is used for etching the second interlayer insulating film 108 to form the trench 109. On the other hand, in accordance with the etching selective ratio, an etching protection film is formed at the lower portion of the second interlayer insulating film 108 to be used as an etching stopper layer at the time of the trench formation.

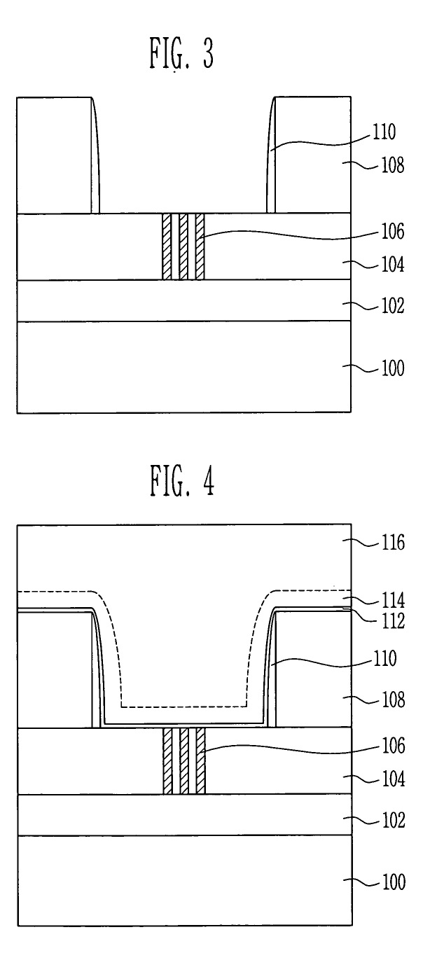

Referring to FIG. 3, a spacer insulating film is deposited along the step difference on the product where the trench 109 is formed, and subsequently, an anisotropic-dry-etching process is carried out to form a spacer 110. The spacer insulating film is formed by using an Si₃N₄ film or an SiC film which has a mechanical strength stronger than that of the second interlayer insulation film 108 and can be used as a metal diffusion barrier film. Since the second interlayer insulating film 108 having a low dielectric constant is vulnerable to a mechanical stress generated in a chemical mechanical polishing (CMP) process, or the like, the spacer is formed on the side wall of the trench formed in the second interlayer insulating film 108 in order to compensate for its vulnerability. It is preferable that the spacer insulating film is deposited by using a plasma-enhanced chemical vapor deposition (PE-CVD) method at a temperature in the range of 200° C. to 450° C. under a pressure in the range of 0.01 torr to 500 torr. The spacer insulating film is deposited to have a thickness in the range of 50 Å to 1500 Å. The anisotropic-drying-etching process is carried out by using a reactive ion etching method.

Referring to FIG. 4, a diffusion barrier film 112 is deposited along the step difference on the product where the spacer 110 is formed. The diffusing barrier film 112 is deposited to have a thickness of 100 Å to 1500 Å. The diffusing barrier film 112 may be formed by using a Ta film, a Ti film, a TaN film, a TiN film, or the like, which has a good adhesive property to the second interlayer insulating film 108 and a metal line which is to be formed during the subsequent process and is capable of preventing metals from being diffused.

A copper seed layer 114 is formed on the diffusion barrier film 112. The copper seed layer 114 is formed to have a thickness in the range of 500 Å to 2000 Å.

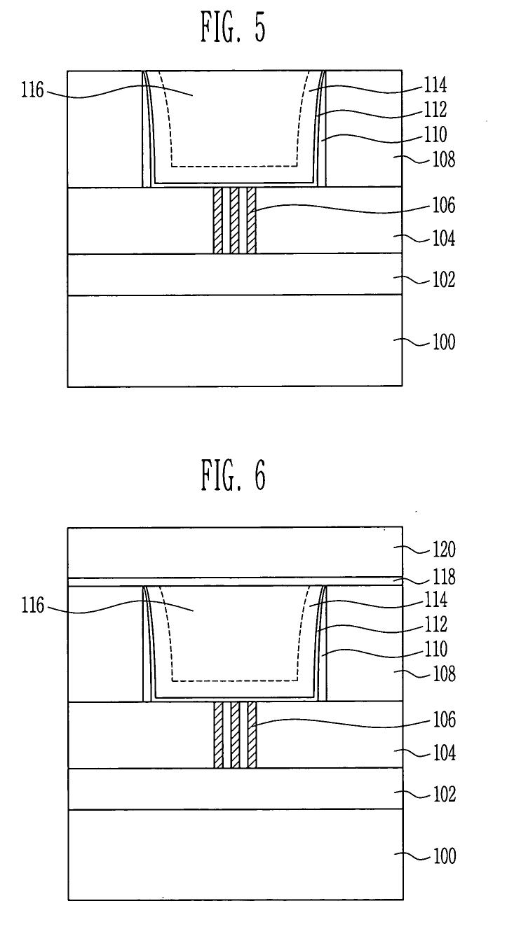

Referring to FIG. 5, a copper film 116 is buried in the trench by using an electroplating method on the copper seed layer 114. The copper film 116 is formed to have a thickness greater than that of the second interlayer insulating film 108, so that it may have a thickness of, 0.5 μm to an order of 10 μm, for example. Next, an annealing process is carried out to densify the copper film 116.

A chemical mechanical polishing process is carried out to remove the copper film 116, the copper seed layer 114, and the diffusion barrier film 112 above the second interlayer insulating film 108. By such a chemical mechanical polishing process, a planarized upper line is formed.

Referring to FIG. 6, a first passivation film 118 is formed on the product where the upper line is formed. The first passivation film 118 is formed by using an Si₃N₄ film or an SiC film to have a thickness in the range of 500 Å to 1500 Å. Next, a second passivation film 120 is formed on the first passivation film 118. The second passivation film 120 is formed by using a TEOS film to have a thickness in the range of 1,000 Å to 10,000 Å for wire bonding. If bonding method is chanced, the passivation thickness and structure can be changed.

The first and second passivation films 118 and 120 are patterned to form an opening portion (not shown) for forming a pad. A diffusion barrier film is deposited along the step difference on the product where the opening portion for forming the pad is formed. The diffusion barrier film is formed to have a thickness in the range of 100 Å to 1000 Å. The diffusing barrier film may be formed by using a Ta film, a Ti film, a TaN film, a TiN film, or the like, which has a good adhesive property to the metal line and is capable of preventing metals which is to be formed as the pad from being diffused.

A conductive film is deposited on the diffusion barrier film and a pattering is carried out to form the pad (not shown). The pad may be formed by using a metal film such as an Al film and so on.

According to the method of forming the metal line of the semiconductor of the present invention, the CMP process is carried out with using a substance having a strong mechanical strength such as Si₃N₄ film, or the like, as the spacer for the interlayer insulating film to compensate for the weak mechanical strength of the low dielectric oxide film, so that it is possible to minimize of occurrence of breakage of the interlayer insulating film and erosion of the oxide film which occurs due to the CMP process. In addition, the diffusion of Cu atoms in the subsequent thermal annealing process is suppressed by using the spacer insulating film, so that it is possible to improve the reliability of the line of the semiconductor devices.

Furthermore, according to the present invention, the dishing in the metal line can be minimized, so that it is possible to obtain the high value of the quality factor (Q) and to minimize of physical failures of the metal line.

Moreover, the spacer oxide film on the side wall of the trench can improve the layer covering property of the Cu diffusion barrier film in the Cu line, so that it is possible to improve the properties of the diffusion barrier film.

Although the foregoing description has made with reference to the preferred embodiments, it is to be understood that changes and modifications of the present invention may be made by the ordinary skilled in the art without departing from the spirit and scope of the present invention and appended claims.

What is claimed is:

1. A method for forming a metal line of a semiconductor device comprising the steps of:
forming a via plug on a semiconductor substrate;
forming an interlayer insulating film on the semiconductor substrate, on which the via plug is formed;
forming a trench by patterning the interlayer insulating film in order to form an upper line to be connected to the via plug;
depositing a spacer insulating film, which is more invulnerable to a mechanical stress than the interlayer insulating film, on the semiconductor substrate on which the trench is formed;
forming a spacer on a side wall of the trench by performing an anisotropic-dry-etching of the spacer insulating film; and
forming a metal line by burying the trench with a conductive material.

2. The method of claim 1, wherein the spacer insulating film is formed by using an Si₃N₄ film or an SiC film which has a mechanical strength stronger than that of the interlayer insulation film and can be used as a metal diffusion barrier film.

3. The method of claim 2, wherein the spacer insulating film is deposited by using a plasma-enhanced chemical vapor deposition (PE-CVD) method at a temperature in the range of 200° C. to 450° C. under a pressure in the range of 0.01 torr to 500 torr.

4. The method of claim 1, wherein the spacer insulating film is deposited to have a thickness in the range of 50 Å to 1500 Å.

5. The method of claim 1, wherein the anisotropic-drying-etching is a reactive ion etching.

6. The method of claim 1, wherein the interlayer insulating film is an oxide film having a lower dielectric constant and formed by using an spin on glass (SOG) film, an fluorine doped tetra ethyl ortho silicate (F-TEOS) film, a carbon doped dielectric (COD) film or a porous low dielectric oxide film.

7. The method of claim 1, wherein the step of forming the via plug comprises the steps of:
forming a lower line on the semiconductor substrate;
forming a second interlayer insulating film on the semiconductor substrate, on which the lower line is formed;
forming a via hole by patterning the second interlayer insulating film in order to connect the lower line with the upper line; and
forming a via plug by burying the via hole with a conductive metal.

8. The method of claim 1, wherein the step of forming the metal line comprises the steps of:
depositing a diffusion barrier film along a step difference of the semiconductor substrate on which the spacer is formed;
depositing a copper seed layer on the diffusion barrier film;
forming a copper film on the copper seed layer by using an electroplating method, thereby burying an opening portion; and
forming the metal line by planarizing the copper film.
